(19) United States
(12) Patent Application Publication
(10) Pub. No.: US 2026/0239630 A1
(43) Pub. Date: Aug. 13, 2026

(54) SEMICONDUCTOR STRUCTURE, FORMING METHOD THEREOF, SEMICONDUCTOR DEVICE AND MEMORY SYSTEM

(71) Applicant: YANGTZE MEMORY TECHNOLOGIES CO., LTD., Wuhan (CN)

(72) Inventors: Danyang WEI, Wuhan (CN); Baoqing SUN, Wuhan (CN); Yu WANG, Wuhan (CN); Liang CHEN, Wuhan (CN); Wei LIU, Wuhan (CN); ZongLiang HUO, Wuhan (CN)

(21) Appl. No.: 19/236,589

(22) Filed: Jun. 12, 2025

(30) Foreign Application Priority Data
Feb. 11, 2025 (CN) 2025101522524

(51) Int. Cl. H01L 23/00; H01L 23/48; H01L 25/18; H10B 80/00; H10D 80/30

(52) U.S. Cl. CPC H10B 80/00; H10D 80/30; H10W 90/00; H10W 20/20; H10W 72/926; H10W 72/932; H10W 72/936; H10W 80/312; H10W 80/327; H10W 90/792

(57) ABSTRACT

In a semiconductor structure, an array of memory cells is disposed in the first semiconductor structure, first and second conductive pads are disposed at a surface of the semiconductor structure, the array of memory cells is connected with the first and second conductive pads respectively at least through different contact structures, the contact structures at least partially extending through the semiconductor structure along a first direction perpendicular to the surface of the semiconductor structure, the second conductive pad is a conductive pad for supplying power with a surface connected with at least one conductive line. The first conductive pad has a shape of at least one of a polygon with more than 4 sides, a circle or an ellipse, and a second conductive pad has a shape of quadrangle.

### CROSS-REFERENCE TO RELATED APPLICATIONS

The present disclosure claims priority to Chinese Patent Application No. 2025101522524, which was filed Feb. 11, 2025, and is hereby incorporated herein by reference in its entirety.

### TECHNICAL FIELD

The present disclosure relates to the technical field of memory, in particular to a semiconductor structure, a forming method thereof, a semiconductor device and a memory system.

### BACKGROUND

With the development of semiconductor technology, the feature size of semiconductor device is scaling down, the integration level is increasingly higher, the process and manufacturing technology of planar memory cells becomes challenging and costly, and thus a three-dimensional semiconductor structure has emerged. The three-dimensional semiconductor structure may comprise an array of memory cells and a peripheral circuit structure for controlling signals input to and output from the array of memory cells.

Those disclosed in this section is merely for facilitating understanding the background of the present disclosure, so it may include information that does not constitute prior art known to those of ordinary skill in the art.

### SUMMARY

The present disclosure provides a semiconductor structure, a forming method thereof, a semiconductor device and a memory system.

Other features and advantages of the present disclosure will become apparent from the following detailed description, or may be learned partially by practice of the present disclosure.

According to an aspect of the present disclosure, a semiconductor structure is provided, comprising: a first semiconductor structure comprising an array of memory cells; a first conductive pad and a second conductive pad disposed at a surface of the semiconductor structure, where the array of memory cells is connected with the first conductive pad and the second conductive pad respectively at least through different contact structures, the contact structures at least partially extending through the semiconductor structure along a first direction, and the first direction is perpendicular to the surface of the semiconductor structure, where the first conductive pad is at least one of a polygon, a circle or an ellipse, and the polygon has more than 4 sides; a surface of the second conductive pad is connected with at least one conductive line, and the second conductive pad is a quadrangle.

According to an example of the present disclosure, the first conductive pad and the second conductive pad each have a first inner diameter and a second inner diameter perpendicular to each other, where a length of the first inner diameter of the first conductive pad is equal to a length of the first inner diameter of the second conductive pad, and a length of the second inner diameter of the first conductive pad is equal to a length of the second inner diameter of the second conductive pad.

According to an example of the present disclosure, an area of the first conductive pad is smaller than an area of the second conductive pad.

According to an example of the present disclosure, the semiconductor structure further comprises a second semiconductor structure, a first surface of the second semiconductor structure is connected with the first semiconductor structure; and the first conductive pad and the second conductive pad are both disposed at a second surface of the second semiconductor structure.

According to an example of the present disclosure, the second semiconductor structure comprises a peripheral circuit structure connected with the array of memory cells, the contact structure comprises a first through substrate contact structure extending through a substrate of the peripheral circuit structure, and the peripheral circuit structure is connected with a corresponding one of the first conductive pad or the second conductive pad at least through the first through substrate contact structure.

According to an example of the present disclosure, the contact structure further comprises a second through substrate contact structure extending through the substrate of the peripheral circuit structure, and the array of memory cells is connected with a corresponding one of the first conductive pad or the second conductive pad at least through the second through substrate contact structure.

According to an example of the present disclosure, the semiconductor structure further comprises a connection structure, the contact structure is connected with a corresponding one of the first conductive pad or the second conductive pad through the connection structure.

According to an example of the present disclosure, the semiconductor structure further comprises a passivation layer disposed around at least one of the first conductive pad or the second conductive pad, and two inner diameters perpendicular to each other of a surface of at least one of the first conductive pad or the second conductive pad exposed from the passivation layer are the first inner diameter and the second inner diameter, respectively.

According to an example of the present disclosure, the first conductive pad is a regular polygon.

According to an example of the present disclosure, the first conductive pad is an octagon or a hexadecagon.

According to an example of the present disclosure, the second conductive pad is a rectangle, and a length and a width of the second conductive pad are the first inner diameter and the second inner diameter, respectively.

According to another aspect of the present disclosure, a method of forming a semiconductor structure is provided, comprising: forming a first semiconductor structure comprising an array of memory cells; forming a second semiconductor structure on a substrate, the second semiconductor structure comprising a peripheral circuit structure; bonding a first surface of the second semiconductor structure with the first semiconductor structure to connect the peripheral circuit structure with the array of memory cells; forming a contact structure extending through the substrate along a first direction perpendicular to the first surface; forming a first conductive pad and a second conductive pad connected with different contact structures respectively at a second surface of the second semiconductor structure to connect the array of memory cells with the first conductive pad and the second conductive pad, the second surface being opposite to the first surface, where the first conductive pad is at least one of a polygon, a circle or an ellipse, the polygon has more than 4 sides, and the second conductive pad is a quadrangle; and forming at least one conductive line connected with a surface of the second conductive pad.

According to an example of the present disclosure, the first conductive pad and the second conductive pad each have a first inner diameter and a second inner diameter perpendicular to each other, where a length of the first inner diameter of the first conductive pad is equal to a length of the first inner diameter of the second conductive pad, and a length of the second inner diameter of the first conductive pad is equal to a length of the second inner diameter of the second conductive pad.

According to an example of the present disclosure, an area of the first conductive pad is smaller than an area of the second conductive pad.

According to an example of the present disclosure, forming the second semiconductor structure on the substrate comprises: forming the peripheral circuit structure on a first surface of the substrate; and forming a first connection structure connected with the peripheral circuit structure on a second surface of the substrate.

According to an example of the present disclosure, the contact structure comprises a first through substrate contact structure; forming the contact structure extending through the substrate along the first direction comprises: forming a first through substrate contact structure extending through the substrate, where the first through substrate contact structure is connected with the first connection structure; and forming a first conductive pad and a second conductive pad connected with different contact structures respectively at the second surface of the second semiconductor structure comprises: forming the first conductive pad or the second conductive pad connected with the first through substrate contact structure at the second surface of the second semiconductor structure.

According to an example of the present disclosure, the contact structure further comprises a second through substrate contact structure; forming the second semiconductor structure on the substrate further comprises: forming a second connection structure connected with the array of memory cells on the first surface of the substrate; the method further comprises: forming the second through substrate contact structure extending through the substrate, where the second through substrate contact structure is connected with the second connection structure; and forming the first conductive pad and the second conductive pad connected with different contact structures respectively at the second surface of the second semiconductor structure comprises: forming the first conductive pad or the second conductive pad in contact with the second through substrate contact structure at the second surface of the second semiconductor structure.

According to an example of the present disclosure, the method further comprises: forming a passivation layer at a surface of at least one of the first conductive pad or the second conductive pad; and removing at least a portion of the passivation layer to expose a portion of the surface of at least one of the first conductive pad or the second conductive pad, where two inner diameters perpendicular to each other of the surface of at least one of the first conductive pad or the second conductive pad exposed from the passivation layer are the first inner diameter and the second inner diameter, respectively.

According to an example of the present disclosure, the first conductive pad is a regular polygon.

According to an example of the present disclosure, the first conductive pad is an octagon or a hexadecagon.

According to an example of the present disclosure, the second conductive pad is a rectangle, and the length and the width of the second conductive pad are the first inner diameter and the second inner diameter, respectively.

According to yet another aspect of the present disclosure, a semiconductor device is provided, comprising any one of the above semiconductor structures.

According to still another aspect of the present disclosure, a memory system is provided, comprising the semiconductor device as described above and a controller coupled to the semiconductor device.

It should be understood that the above general description and the following detailed description are only examples and are not intended to limit the present disclosure.

### BRIEF DESCRIPTION OF THE DRAWINGS

The above and other objectives, features, and advantages of the present disclosure will become more apparent from the following detailed description in conjunction with accompanying drawings.

FIG. 1 is a block diagram of an example system with a memory according to an example of the present disclosure.

FIG. 2A illustrates a block diagram of a memory system.

FIG. 2B illustrates a block diagram of another memory system.

FIG. 3 illustrates a cross-sectional view of a semiconductor structure according to an example.

FIG. 4A illustrates a schematic diagram of a shape of a first conductive pad according to an example.

FIG. 4B illustrates a schematic diagram of another shape of a first conductive pad according to an example.

FIG. 4C illustrates a schematic diagram of yet another shape of a first conductive pad according to an example.

FIG. 4D illustrates a schematic diagram of still another shape of a first conductive pad according to an example.

FIG. 5 illustrates a schematic diagram of a shape of a second conductive pad according to an example.

FIG. 6 illustrates a cross-sectional view of another semiconductor structure according to an example.

FIG. 7 is a flow diagram illustrating a method of forming a semiconductor structure according to an example.

FIG. 8 illustrates a schematic diagram of a process of operation S704 shown in FIG. 7 in an example.

FIG. 9 illustrates a schematic diagram of a process of operations S708 and S710 shown in FIG. 7 in an example.

FIG. 10 illustrates a schematic diagram of a process of operations S704, S708 and S710 shown in FIG. 7 in an example.

FIG. 11 is a flow diagram illustrating another method of forming a semiconductor structure according to an example.

FIG. 12 illustrates a cross-sectional view of a substrate of a first semiconductor structure according to an example.

FIG. 13 illustrates a cross-sectional view of a first semiconductor structure formed on a substrate according to an example.

FIG. 14 illustrates a cross-sectional view of a substrate of a second semiconductor structure according to an example.

FIG. 15 illustrates a cross-sectional view of a peripheral circuit structure formed on a substrate according to an example.

FIG. 16 illustrates a cross-sectional view of a bonding layer formed on a first semiconductor structure and a second semiconductor structure according to an example.

FIG. 17 illustrates a cross-sectional view of the first and second semiconductor structures bonded together according to an example.

FIG. 18 illustrates a cross-sectional view of a conductive pad formed at a surface of a second semiconductor structure according to an example.

### DETAILED DESCRIPTION

Examples will now be described more fully with reference to the accompanying drawings. However, the examples can be implemented in a variety of forms and should not be construed as limited to the those set forth herein; rather, these examples are provided so that the present disclosure will be more comprehensive and complete and fully convey the concepts of the examples to those skilled in the art. The drawings are merely schematic illustrations of the present disclosure and are not necessarily drawn to scale. Like reference numerals in the drawings refer to the same or similar parts, and repeated description thereof will be omitted.

Furthermore, the described features, structures, or characteristics may be incorporated in one or more examples in any suitable manner. In the following description, numerous specific details are provided to give a thorough understanding of examples of the present disclosure. However, those skilled in the art will appreciate that the technical solutions of the present disclosure may be practiced with one or more of the specific details omitted, or other methods, devices, operations, etc., may be employed. In other cases, well-known structures, methods, devices, implementations, or operations are not shown or described in detail to avoid obscuring aspects of the present disclosure.

In addition, the terms “first”, “second” and so on are used for descriptive purposes only and are not to be construed as indicating or implying relative importance or implicitly indicating the number of indicated technical features. Thus, features defining “first”, “second” may explicitly or implicitly include one or more of the features. In the description of the present disclosure, the meaning of “a plurality of” is at least two, for example, two, three, etc., unless specifically defined otherwise. The symbol “/” generally indicates that the two associated object has an “or” relationship.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (e.g., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

In the present disclosure, the term “substrate” refers to a material onto which a subsequent layer of material is added. The substrate itself may be patterned. The material added on top of the substrate may be patterned or may remain unpatterned. Further, the substrate may comprise a variety of semiconductor materials, such as silicon, germanium, gallium arsenide, indium phosphide, and the like. Alternatively, the substrate may be made of a non-conductive material, such as a glass, plastic, or sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

In the present disclosure, unless otherwise specified and limited, the term such as “connection” should be interpreted in a broad manner, for example, may be electrical connections or may communicate with each other; may be directly connected or indirectly connected by an intermediate medium. For those skilled in the art, the specific meaning of the above terms in the present disclosure may be interpreted according to specific conditions.

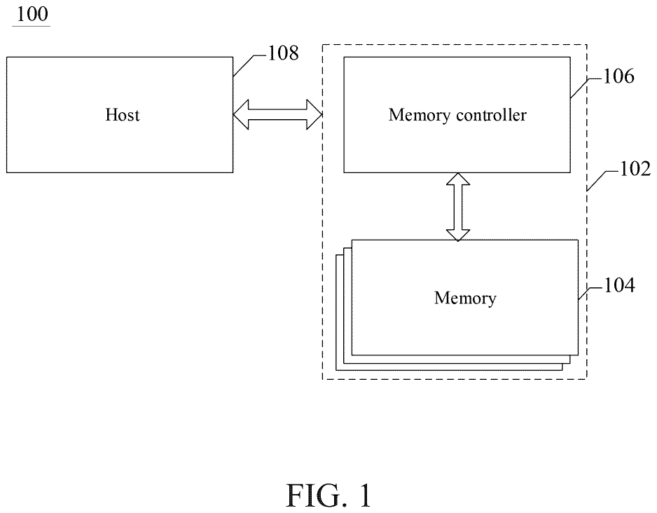

FIG. 1 is a block diagram of an example system with a memory according to an example of the present disclosure. The system 100 may be a mobile phone, a desktop computer, a laptop computer, a tablet computer, a vehicle computer, a game console, a printer, a positioning device, a wearable electronic device, a smart sensor, a virtual reality device, an augmented reality device, or any other suitable electronic device having memories therein.

As shown in FIG. 1, the system 100 may comprise a host 108 and a memory system 102 with one or more memories 104 and a memory controller 106. The host 108 may be a processor of an electronic device (e.g., a central processing unit (CPU)) or a system-on-a-chip (SoC) (e.g., an application processor). The host 108 may be configured to send or receive data to or from the memory 104.

The memory 104 may be a non-volatile memory, a volatile memory, and the like. The non-volatile memory may be a NAND flash memory (e.g., a three-dimensional (3D) NAND flash memory). The volatile memory may be a dynamic random access memory (DRAM).

In some examples, the memory controller 106 is coupled to the memory 104 and the host 108 and is configured to control the memory 104. The memory controller 106 may manage data stored in the memory 104 and communicate with the host 108.

In some examples, the memory controller 106 is configured to send a command to the memory 104, so that the memory 104 executes the memory operation method provided in the examples of the present disclosure.

In some examples, the memory controller 106 is designed to operate in a low duty cycle environment, such as a secure digital (SD) card, a compact flash memory (CF) card, a universal serial bus (USB) flash drive, or other medium for use in electronic devices such as personal computers, digital cameras, mobile phones, and the like.

In some examples, the memory controller 106 is designed to operate in a high duty cycle environment, such as a solid state drive (SSD) or an embedded multimedia card (eMMC), which may be used as a data memory for mobile devices such as smartphones, tablets, laptops, and the like, as well as enterprise storage arrays. The memory controller 106 may be configured to send commands to the memory 104 to instruct the memory 104 to perform operations, such as read, erase, and program operations.

The memory controller 106 may also be configured to manage various functions regarding data stored in or to be stored in the memory 104, including but not limited to, bad block management, garbage collection, logical-to-physical address translation, wear leveling, etc.

In some examples, the memory controller 106 is further configured to process error correction codes (ECC) regarding data read from or written to the memory 104. The memory controller 106 may also perform any other suitable functions, such as formatting memory 104. The memory controller 106 may communicate with an external device (e.g., host 108) according to a particular communication protocol. For example, the memory controller 106 may communicate with external devices through at least one of a variety of interface protocols, such as a USB protocol, an MMC protocol, a Peripheral Component Interconnect (PCI) protocol, a PCI Express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, and the like.

The memory controller 106 and the one or more memories 104 may be integrated into various types of memory devices, e.g., included in the same package (e.g., a Universal Flash Storage (UFS) package or an eMMC package). For example, the memory system 102 may be implemented and packaged into different types of end electronic products.

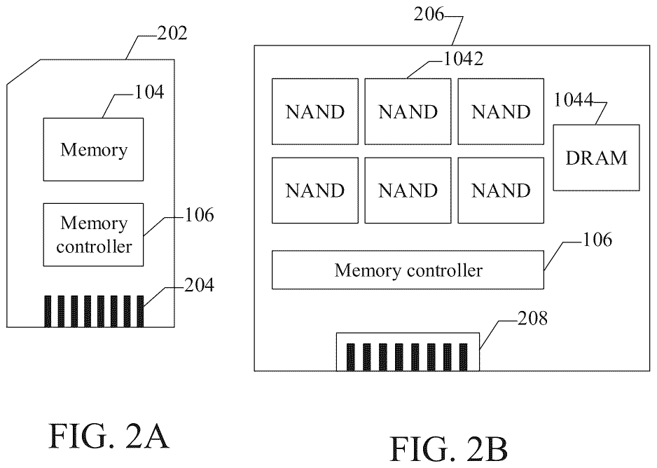

FIG. 2A illustrates a block diagram of a memory system. As shown in FIG. 2A, the memory controller 106 and a single memory 104 may be integrated into the memory card 202. The memory card 202 may include a PC card (also referred to as a PCMCIA card, a personal computer memory card international association card), a CF card, a smart media (SM) card, a memory stick, a multimedia card (e.g., an MMC card, an RS-MMC card, an MMCmicro card, etc.) , an SD card (e.g., an SD card, a miniSD card, a microSD card, an SDHC card, etc.) , a UFS card, and the like. The memory card 202 may also include a memory card connector 204 that couples the memory card 202 with a host (e.g., host 108 in FIG. 1).

FIG. 2B illustrates a block diagram of another memory system. As shown in FIG. 2B, the memory controller 106 and a plurality of memories 104 may be integrated into the SSD 206, and the plurality of memories 104 may include, for example, a plurality of NAND flash memories 1042 and one DRAM 1044. The SSD 206 may also include an SSD connector 208 that couples SSD 206 with a host (e.g., host 108 in FIG. 1). In some examples, the storage capacity and/or operating speed of the SSD 206 is greater than that of the memory card 202.

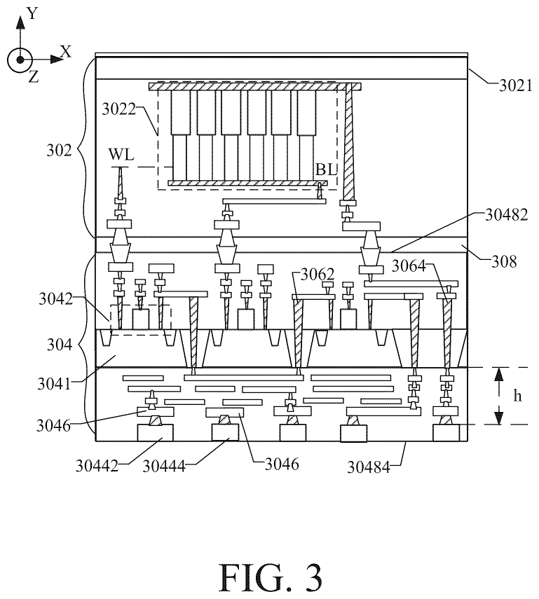

FIG. 3 illustrates a cross-sectional view of a semiconductor structure according to an example. The semiconductor structure provided by examples of the present disclosure may be a semiconductor device, for example, may be the DRAM memories in FIG. 1 to FIG. 2B. The semiconductor structure shown in FIG. 3 may comprise a first semiconductor structure 302, and the array of memory cells 3022 is disposed in the first semiconductor structure 302.

Referring to FIG. 3, the first semiconductor structure 302 may comprise an array of memory cells 3022 disposed on a substrate 3021. The array of memory cells 3022 may comprise DRAM cells of pairs of a transistor and a capacitor (not labeled in FIG. 3) forming an array in a plane formed in the X direction and the Z direction. The word line (WL) and the bit line (BL) intersect in a plane formed in the X direction and the Z direction, and a DRAM cell is formed at the intersection between the WL and the BL.

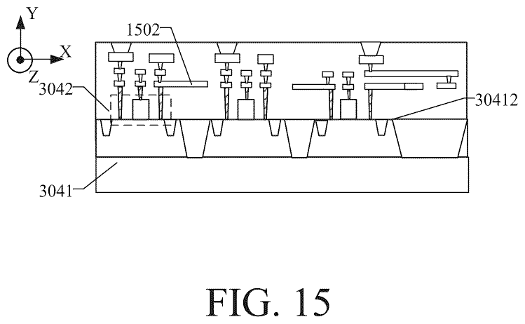

The semiconductor structure shown in FIG. 3 may further comprise a first conductive pad 30442 and a second conductive pad 30444 disposed at a surface of the semiconductor structure. The array of memory cells 3022 is connected with the first conductive pad 30442 and the second conductive pad 30444 respectively by at least different contact structures (for example, the first through substrate contact structure 3062 and the second through substrate contact structure 3064 in FIG. 3), and the contact structures at least partially extend through the semiconductor structure along a first direction perpendicular to the surface of the semiconductor structure (e.g., the Y direction in FIG. 3). The first conductive pad 30442 and the second conductive pad 30444 may both be electrically connected with a connection structure (for example, which may include the first connection structure 3046 and the second connection structure 1502 in FIG. 15) inside the semiconductor structure, and the connection structure is electrically connected with the contact structure, thereby electrically connecting at least one of the peripheral circuit structure 3042 or the array of memory cells 3022 to a corresponding one of the first conductive pad 30442 or the second conductive pad 30444, and the connection structure may be, for example, at least a part of the metal layer. The first conductive pad 30442 and the second conductive pad 30444 may each be a metal material, for example, may be one or more of copper, nickel, aluminum, silver, gold, and the like.

The first conductive pad 30442 may be a conductive pad for transmitting data to the array of memory cells 3022 through the peripheral circuit structure 3042 from the outside and/or transmitting data in the array of memory cells 3022 to the outside through the peripheral circuit structure 3042, and may be, for example, a conductive pad for transmitting a clock signal, a conductive pad for transmitting a data queue, a conductive pad for transmitting commands and addresses, and a conductive pad for transmitting signals implementing functions such as data masking and data bus inversion. A surface of the second conductive pad 30444 (e.g., an exposed portion of the surface of the semiconductor structure) is connected with at least one conductive line (not shown in FIG. 3) that is led out from the metal surface of the second conductive pad 30444 and extends towards the interior of the semiconductor structure and may extend to be connected with at least one of the peripheral circuit structure 3042 or the array of memory cells 3022 to provide power supply for at least one of the peripheral circuit structure 3042 or the array of memory cells 3022. For example, the second conductive pad 30444 may be a conductive pad for supplying power to the semiconductor structure as an external power supply.

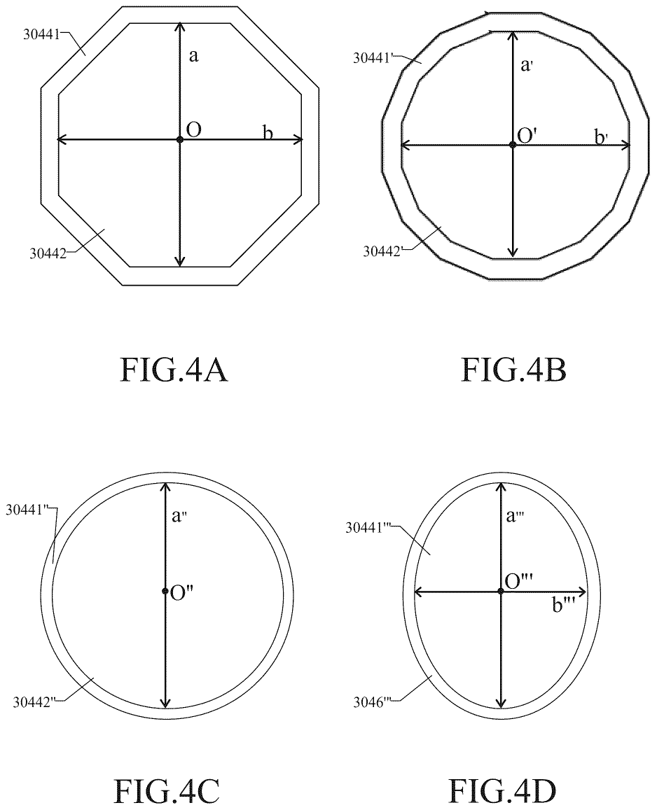

The first conductive pad 30442 may be at least one of a polygon with more than 4 sides, a circle or an ellipse. An example of the shape of the first conductive pad 30442 may be referred to FIG. 4A to FIG. 4D. The second conductive pad 30444 may be a quadrangle.

According to the semiconductor structure provided in the example of the present disclosure, the array of memory cells is disposed in the first semiconductor structure, a first conductive pad and a second conductive pad are disposed at a surface of the semiconductor structure, the array of memory cells is connected with the first conductive pad and the second conductive pad respectively at least through different contact structures, the contact structures at least partially extend through the semiconductor structure along a first direction perpendicular to the surface of the semiconductor structure. The first conductive pad is configured for transmitting data, and the second conductive pad is a conductive pad configured for supplying power with a surface connected with at least one conductive line. The first conductive pad has a shape of at least one of a polygon with more than 4 sides, a circle or an ellipse, and a second conductive pad has a shape of quadrangle, such that while ensuring the package size of the conductive pad, the area of the first conductive pad is reduced to reduce the parasitic capacitance between the first conductive pad and the substrate, and the area of the second conductive pad can be maintained to increase the stability of power supply of the external power supply.

In some examples, the semiconductor structure may further comprise a second semiconductor structure, the peripheral circuit structure is disposed in the second semiconductor structure, and the first semiconductor structure and the second semiconductor structure may be bonded together by the bonding layer, thereby electrically connecting the array of memory cells with the peripheral circuit structure. With continued reference to FIG. 3, the first semiconductor structure 302 and the second semiconductor structure 304 may be stacked together along the Y direction in FIG. 3 to form a frame of the memory.

As shown in FIG. 3, the second semiconductor structure 304 may comprise a peripheral circuit structure 3042 disposed on the substrate 3041, and the peripheral circuit structure 3042 is connected with the array of memory cells 3022. The peripheral circuit structure 3042 may comprise any suitable digital, analog, and/or mixed-signal peripheral circuit for facilitating operation of the array of memory cells 3022, for example, a row decoder/word line (WL) driver, a page buffer/sense amplifier, a column decoder/bit line (BL) driver, an address register, a control logic unit, and an input/output (I/O) circuit, among others.

The first surface 30482 of the second semiconductor structure 304 is connected with the first semiconductor structure 302, and the first conductive pad 30442 and the second conductive pad 30444 are both on the second surface 30484 of the second semiconductor structure 304. The first surface 30482 and the second surface 30484 of the second semiconductor structure 304 are two opposite surfaces. The first surface 30482 may be, for example, a front surface of the second semiconductor structure 304, and the second surface 30484 may be, for example, a back surface of the second semiconductor structure 304.

The bonding layer 308 between the first semiconductor structure 302 and the second semiconductor structure 304 may be a bonding layer between two semiconductor structures formed by any suitable bonding technique described in detail below, which may be, for example, one or more of hybrid bonding, anodic bonding, fusion bonding, transfer bonding, adhesive bonding, and eutectic bonding.

In some examples, the contact structure may comprise a through substrate contact structure extending through the substrate of the peripheral circuit structure along a first direction. Two through substrate contact structures, e.g., a first through substrate contact structure 3062 and a second through substrate contact structure 3064, are shown in FIG. 3 as an example. The peripheral circuit structure 3042 is connected with the corresponding one of the first conductive pad 30442 or the second conductive pad 30444 at least through the first through substrate contact structure 3062, for example, the peripheral circuit structure 3042 is connected with the corresponding one of the first conductive pad 30442 or the second conductive pad 30444 through the metal layer in the second semiconductor structure 304 and the first through substrate contact structure 3062. The array of memory cells 3022 is connected with the corresponding one of the first conductive pad 30442 or the second conductive pad 30444 at least through the second through substrate contact structure 3064, for example, the array of memory cells 3022 is connected with the corresponding one of the first conductive pad 30442 or the second conductive pad 30444 through the metal layer in the first semiconductor structure 302, the second through substrate contact structure 3064, and the metal layer in the second semiconductor structure 304 sequentially.

According to the semiconductor structure provided by an example of the disclosure, the array of memory cells is disposed in the first semiconductor structure, the peripheral circuit structure is disposed in the second semiconductor structure, the first conductive pad and the second conductive pad connected with at least one of the array of memory cells or the peripheral circuit structure are disposed on the opposite surface to the surface of the second semiconductor structure connected with the first semiconductor structure, so that during the process of connecting the BL in the array of memory cells with the peripheral circuit structure (for example, the sensing amplifier circuit), the BL does not need to pass through the power supply metal layer, and the routing length of the BL to the sensing amplifier circuit is reduced. On the other hand, the crosstalk between the power supply metal layer and other signal lines on the connection line of the BL to the sensing amplifier circuit is reduced, and the influence on the sensing tolerance in the memory operation process is also reduced.

In an example of the present disclosure, the first semiconductor structure and the second semiconductor structure are bonded to form the semiconductor structure, and the conductive pad is disposed at the surface of the second semiconductor structure. In such a case, the distance between the conductive pad and the substrate of the second semiconductor structure is relatively close (the distance h as shown in FIG. 3). As a result, the parasitic capacitance generated may affect the quality of data transmission, especially for the first conductive pad configured for data transmission. The first conductive pad has a shape of at least one of a polygon with more than 4 sides, a circle or an ellipse, such that the area of the first conductive pad can be reduced to reduce the parasitic capacitance between the first conductive pad and the substrate while ensuring the package size of the conductive pad, thereby improving the data transmission quality.

In an example of the present disclosure as illustrated in FIG. 3, as an example rather than limitation, the semiconductor structure is formed by bonding the first conductive pad and the second conductive pad, and the first conductive pad and the second conductive pad are disposed at the surface of the second semiconductor structure connected with the first semiconductor structure. In some other examples, the peripheral circuit structure may also be disposed in the first semiconductor structure, and the first conductive pad and the second conductive pad may be disposed at a surface of the first semiconductor structure away from the substrate. In some other examples, in a case where the semiconductor structure comprises the first semiconductor structure and the second semiconductor structure, the first conductive pad and the second conductive pad may also be disposed at a surface of the first semiconductor structure away from the substrate. The corresponding connections of the first conductive pad and the second conductive pad to the array of memory cells and the peripheral circuit structure in these examples can by implemented by those skilled in the art.

FIG. 4A to FIG. 4D illustrate implementations of the first conductive pads with different shapes.

FIG. 4A illustrates a schematic diagram of a shape of a first conductive pad according to an example. As shown in FIG. 4A, the first conductive pad 30442 may be an octagon.

FIG. 4B illustrates a schematic diagram of another shape of a first conductive pad according to an example. As shown in FIG. 4B, the first conductive pad 30442′ may be a hexadecagon.

In some examples, the first conductive pad may be a regular polygon, for example, it may be a regular octagon in FIG. 4A, and for example, it may be a regular hexadecagon in FIG. 4B.

FIG. 4C illustrates a schematic diagram of yet another shape of a first conductive pad according to an example. As shown in FIG. 4C, the first conductive pad 30442″ may be a circle.

FIG. 4D illustrates a schematic diagram of still another shape of a first conductive pad according to an example. As shown in FIG. 4D, the first conductive pad 30442′″ may be an ellipse.

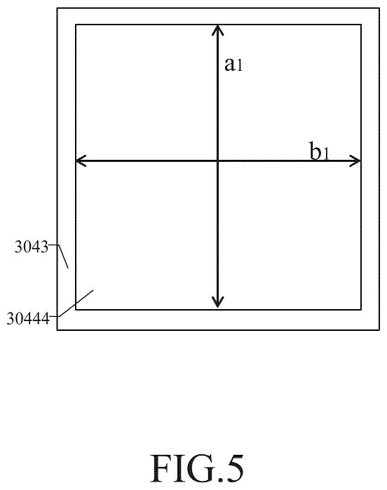

FIG. 5 illustrates a schematic diagram of a shape of a second conductive pad according to an example. As shown in FIG. 5, the second conductive pad 30444 may be a rectangle.

In some examples, the first conductive pad and the second conductive pad each have a first inner diameter and a second inner diameter perpendicular to each other. The inner diameters of the first conductive pad and the second conductive pad may be line segments passing through the center and having two ends on the sides on the exposed conductive surface of the first conductive pad and the second conductive pad, where the first inner diameter and the second inner diameter may be two of the line segments perpendicular to each other.

Referring to FIG. 4A to FIG. 5, in FIG. 4A, for the octagonal first conductive pad 30442, the first inner diameter a and the second inner diameter b are line segments perpendicular to each other, passing through its center O and having two ends on the two opposite sides. In FIG. 4B, for the hexadecagonal first conductive pad 30442′, the first inner diameter a′ and the second inner diameter b′ are line segments perpendicular to each other, passing through its center O′ and having two ends on the two opposite sides. In FIG. 4C, for a circular first conductive pad 30442″, the first inner diameter a″ is one diameter (through its center O″), and the second inner diameter (not shown in FIG. 4C) is another diameter perpendicular to a″. In FIG. 4D, for the elliptical first conductive pad 30442′″, the first inner diameter a′″ may be a long axis (through its center O′″), and the second inner diameter b′″ may be a short axis. In FIG. 5, for the rectangular second conductive pad 30444, the first inner diameter a1 and the second inner diameter b1 may be the length and width of the rectangle, respectively.

In some examples, the first conductive pad is at least one of a polygon with more than 4 sides, a circle or an ellipse, and the second conductive pad is a quadrangle. In such a case, an area of the first conductive pad could be smaller than an area of the second conductive pad by setting a length of the first inner diameter of the first conductive pad to be equal to a length of the first inner diameter of the second conductive pad, and a length of the second inner diameter of the first conductive pad to be equal to a length of the second inner diameter of the second conductive pad. In such a setting, the length of the first inner diameter and the length of the second inner diameter may be correspondingly greater than or equal to the minimum size required for the packaging process.

In some examples, the minimum size required for the corresponding packaging process to the first inner diameter may be the same as or different from the minimum size required for the corresponding packaging process to the second inner diameter, which is not limited in the present disclosure.

According to the semiconductor structure provided by an example of the present disclosure, the first conductive pad is at least one of a polygon with more than 4 sides, a circle or an ellipse, and the second conductive pad is a quadrangle. In such a case, by setting the length of the first inner diameter of the first conductive pad to be equal to the length of the first inner diameter of the second conductive pad, and the length of the second inner diameter of the first conductive pad to be equal to the length of the second inner diameter of the second conductive pad, the area of the first conductive pad could be smaller than the area of the second conductive pad, while still meeting the size requirement on the first conductive pad and the second conductive pad for the packaging, thereby reducing the parasitic capacitance between the first conductive pad and the substrate, and reducing the parasitic capacitance between the first conductive pad and other metal layers in the semiconductor structure.

In some examples, a passivation layer may also be disposed around a surface of at least one of the first conductive pad or the second conductive pad, and may be prevent oxidation of an edge of the surface of the conductive pad. The two inner diameters perpendicular to each other of the surface of at least one of the first conductive pad or the second conductive pad exposed from the passivation layer may be a first inner diameter and a second inner diameter, respectively. In some examples, the passivation layer may comprise an insulating layer, a polymer layer, and the like, where the insulating layer may be a nitride layer, such as a metal nitride layer, and the polymer layer may be a nano polymer, and may prevent scratching or damaging to the edge of the surface of the conductive pad. Referring again to FIG. 4A to FIG. 5, in FIG. 4A, for an octagonal first conductive pad 30442, its passivation layer 30441 is a ring structure having an inner shape and an outer shape of an octagon. In FIG. 4B, for a hexadecagonal first conductive pad 30442′, its passivation layer 30441′ is a ring structure having an inner shape and an outer shape of a hexadecagon. In FIG. 4C, for a circular first conductive pad 30442″, its passivation layer 30441″ is a circular ring. In FIG. 4D, for an elliptical first conductive pad 30442″, its passivation layer 30441″ is an elliptical ring. In FIG. 5, for a rectangular second conductive pad 30444, its passivation layer 30443 is a ring structure having an inner shape and an outer shape of a rectangle.

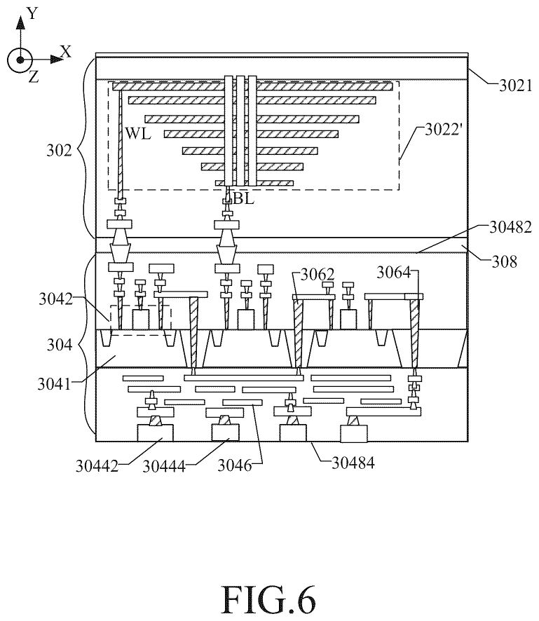

FIG. 6 illustrates a cross-sectional view of another semiconductor structure according to an example. The semiconductor structure provided by examples of the present disclosure may be a semiconductor device, for example, may be the NAND memory in FIG. 1 to FIG. 2B.

The semiconductor structure shown in FIG. 6 may comprise a first semiconductor structure 302, and the array of memory cells 3022 is disposed in the first semiconductor structure 302. The array of memory cells 3022′ may have a stack structure stacked in a vertical direction (e.g., the Y direction in FIG. 6) to provide a gate conductive layer of a transistor (comprising a select gate and a WL), a channel layer of the transistor is provided in a channel structure extending through the stack structure in a direction perpendicular to the stacking direction (e.g., the Y direction in FIG. 6), and a bit line is further formed to connect the channel structure and the memory cell formed by the gate conductive layer. Referring to FIG. 6, the gate conductive layer may extend in a plane formed in the X direction and the Z direction. The array of memory cells 3022′ may be formed at certain regions on the substrate 3021. In some examples, the array of memory cells 3022′ may also be formed as a plurality of memory blocks, and the plurality of memory blocks may be grouped into pages.

The same reference numeral in FIG. 6 and in FIG. 3 may represent the same component. Those skilled in the art can understand that the structures with the same reference numeral as shown in FIG. 6 and in FIG. 3 can be modified according to the differences of DRAM memory and NAND memory in actual operation, and is not limited to be the same structure.

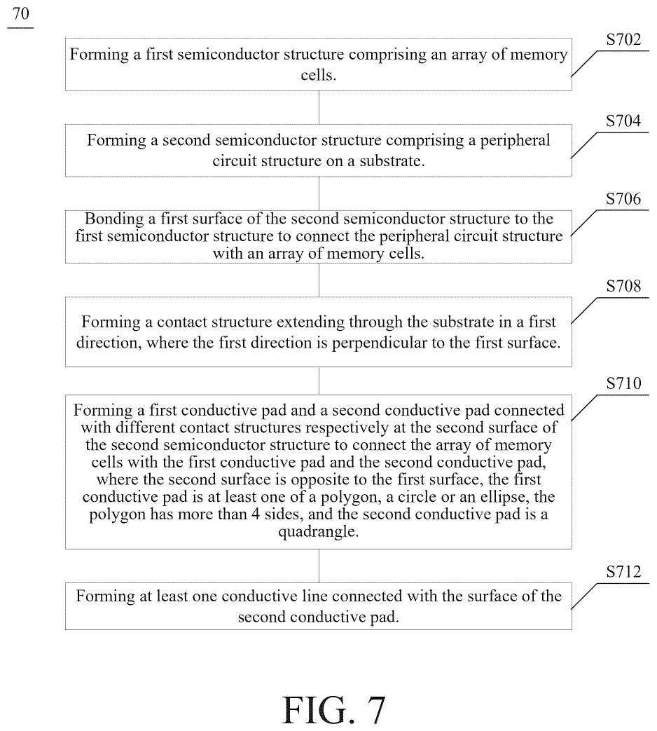

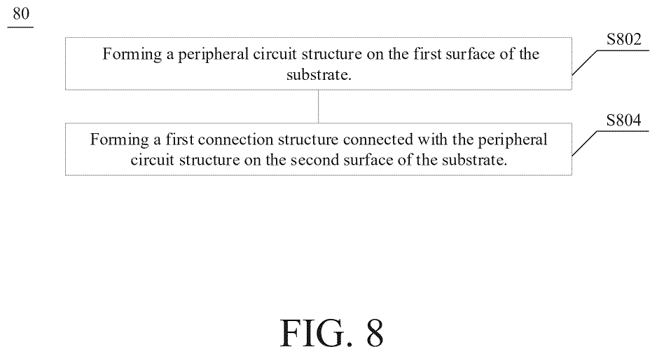

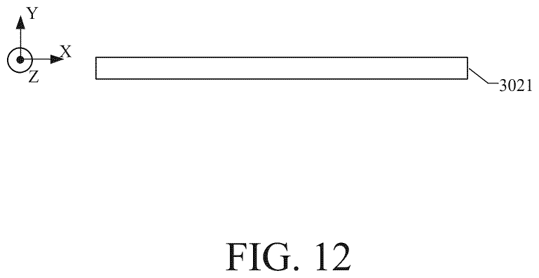

FIG. 7 is a flow diagram illustrating a method of forming a semiconductor structure according to an example. The method shown in FIG. 7 may comprise, for example, operations of forming the semiconductor structure shown in FIG. 3 or FIG. 6. Referring to FIG. 7, a method 70 provided by an example of the present disclosure may comprise the following operations S702 to S712. FIG. 12 to FIG. 18 illustrate cross-sectional views of some process nodes of the semiconductor structure shown in FIG. 3 during the process of formation, and the formation methods in FIG. 7 (and FIG. 8 to FIG. 11) will be described in combination with those cross-sectional views.

In operation S702, a first semiconductor structure comprising an array of memory cells is formed.

FIG. 12 illustrates a cross-sectional view of a substrate of a first semiconductor structure according to an example. As shown in FIG. 12, a substrate 3021 may be provided first. The substrate 3021 may be a single layer substrate or a multilayer substrate, for example, may be a single layer substrate of monocrystalline silicon, a single layer substrate of polysilicon, a multilayer substrate of polysilicon and metal, and the like.

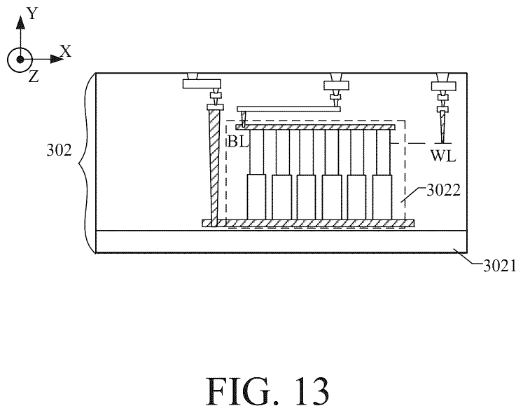

FIG. 13 illustrates a cross-sectional view of a first semiconductor structure formed on a substrate according to an example. For the semiconductor structure shown in FIG. 3, in the process of forming the first semiconductor structure, a transistor, a bit line contact module, a bit line, a storage node contact module, a capacitor and the like may be formed on the substrate 3021, thereby forming the array of DRAM memory cells 3022 on the substrate 3021.

In some other examples, for the semiconductor structure shown in FIG. 6, in the process of forming the first semiconductor structure, a stack structure, a channel structure, and the like may be formed on the corresponding substrate, so as to form an array of NAND memory cells on the substrate.

In operation S704, a second semiconductor structure comprising a peripheral circuit structure is formed on the substrate.

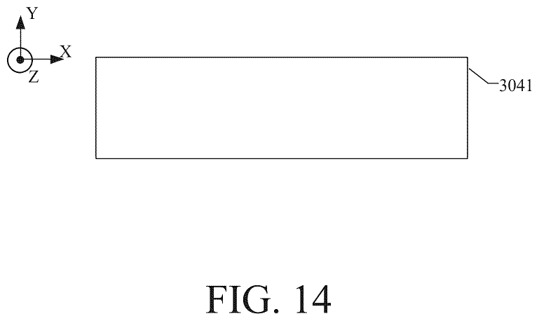

FIG. 14 illustrates a cross-sectional view of a substrate of a second semiconductor structure according to an example. As shown in FIG. 14, a substrate 3041 may be provided first. The substrate 3041 may also be a single layer substrate or a multilayer substrate, for example, may be a single layer substrate of monocrystalline silicon, a single layer substrate of polysilicon, a multilayer substrate of polysilicon and metal, and the like.

FIG. 15 illustrates a cross-sectional view of a peripheral circuit structure formed on a substrate according to an example. In some examples, a peripheral circuit structure may be formed on the substrate 3041, for example, a plurality of peripheral circuit modules (3042 is an example of one of the peripheral circuit modules) may be formed on the substrate 3041, and then a connection structure 1502 is formed to interconnect the peripheral circuit modules.

In operation S706, the first surface of the second semiconductor structure is bonded to the first semiconductor structure to connect the peripheral circuit structure with the array of memory cells.

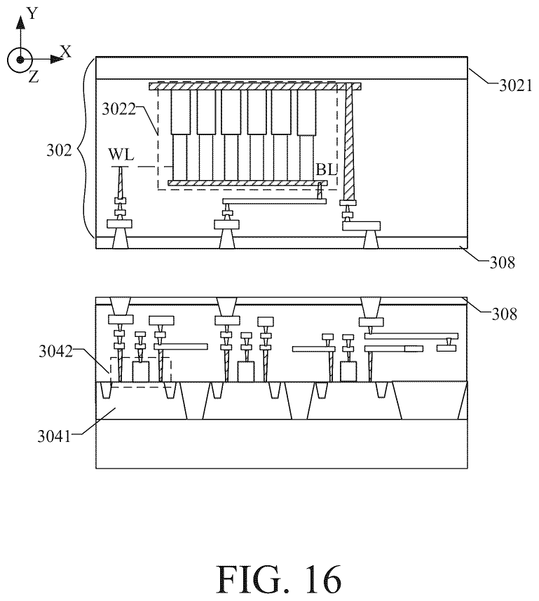

In some examples, a bonding layer may be formed at surfaces of the first semiconductor structure and the second semiconductor structure away from the substrate (e.g., the front side) respectively, so that the first semiconductor structure and the second semiconductor structure are bonded by the bonding layer. FIG. 16 illustrates a cross-sectional view of a bonding layer formed on the first semiconductor structure and the second semiconductor structure according to an example. As shown in FIG. 16, the bonding layer 308 may be formed at a surface of the first semiconductor structure 302 away from the substrate 3021 and disposed at a surface of the second semiconductor structure 304 away from the substrate 3041, respectively. The bonding layer 308 may be an interconnect layer, which may comprise, for example, one or more bonding structures embedded in a dielectric layer. The bonding structure may comprise contacts, single-layer/multi-layer vias, conductive lines, plugs, pads, and/or any other suitable conductive structure made of a conductive material comprising tungsten, cobalt, copper, aluminum, doped silicon, silicide, or any combination thereof. The dielectric layer may comprise a dielectric material comprising silicon oxide, silicon nitride, silicon oxynitride, or any combination thereof.

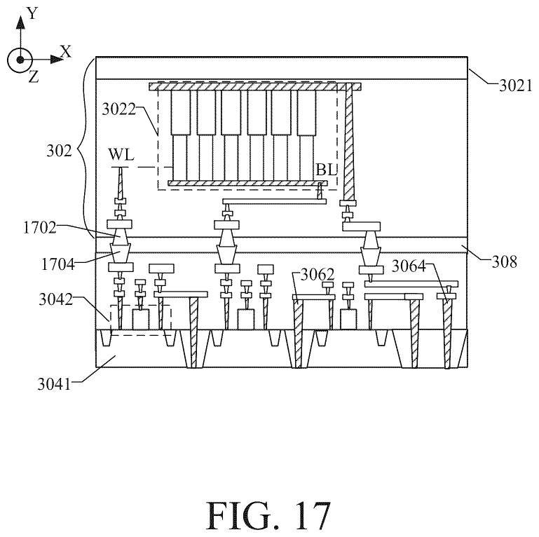

In some examples, one or more bonding structures of the first semiconductor structure and one or more bonding structures of the second semiconductor structure may contact each other at an interface of the bonding layer to achieve an electrical connection. FIG. 17 illustrates a cross-sectional view of the first and second semiconductor structures bonded together according to an example. As shown in FIG. 17, the bonding structure 1402 of the first semiconductor structure 302 and the bonding structure 1404 of the second semiconductor structure 304 contact at the interface of the bonding layer 308 to achieve electrical connection, thereby connecting the array of memory cells 3022 and the peripheral circuit structure 3042.

In operation S708, a contact structure extending through the substrate along a first direction is formed, and the first direction is perpendicular to the first surface.

In some examples, after bonding the first semiconductor structure and the second semiconductor structure, the substrate of the second semiconductor structure may be thinned to a certain thickness for subsequent process manufacturing. For example, referring to FIG. 16 and FIG. 17, the substrate of the second semiconductor structure 304 in FIG. 17 is thinner than the substrate of the first semiconductor structure 302.

With continued reference to FIG. 17, after the substrate 3041 of the second semiconductor structure is thinned, the first through substrate contact structure 3062 and the second through substrate contact structure 3064 extending through the substrate 3041 along the Y direction may be formed, so that the peripheral circuit structure 3042 is lead out through the first through substrate contact structure 3062 and the second through substrate contact structure 3064.

In operation S710, a first conductive pad and a second conductive pad connected with different contact structures respectively at the second surface of the second semiconductor structure are formed, to connect the array of memory cells with the first conductive pad and the second conductive pad. The second surface is opposite to the first surface. The first conductive pad is at least one of a polygon, a circle or an ellipse, the polygon has more than 4 sides, and the second conductive pad is a quadrangle.

In some examples, after forming the contact structure extending through the substrate along the first direction, the routing layer comprising the connection structure may be then formed on the exposed surface of the substrate of the second semiconductor structure.

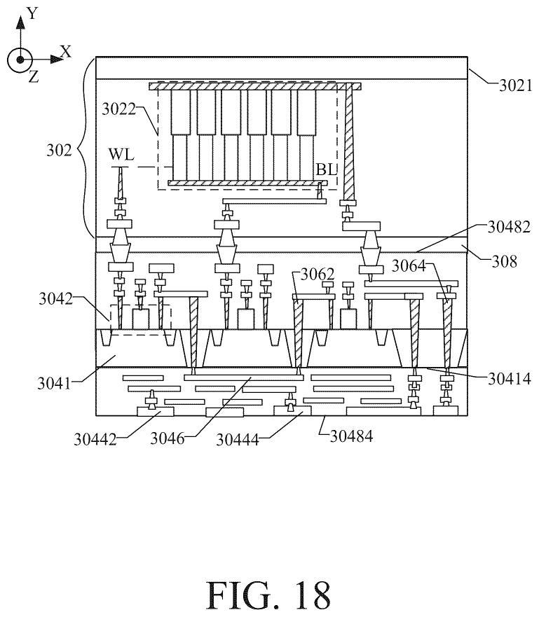

FIG. 18 illustrates a cross-sectional view of a conductive pad formed at a surface of a second semiconductor structure according to an example. As shown in FIG. 18, a routing layer comprising the first connection structure 3046 may be formed at the surface of the substrate 3041 of the second semiconductor structure 304 in FIG. 17, and then the first conductive pad 30442 and the second conductive pad 30444 are formed on the second surface 30484 of the second semiconductor structure 304 outside the routing layer.

In operation S712, at least one conductive line connected with the surface of the second conductive pad is formed.

In some examples, at least one conductive line connected with at least one of the peripheral circuit structure or the array of memory cells may be extended to the second surface of the second semiconductor structure during the formation of the routing layer of the second semiconductor structure, thereby connecting the conductive line to the exposed surface of the second conductive pad to provide power to at least one of the peripheral circuit structure 3042 or the array of memory cells 3022.

FIG. 8 illustrates a schematic diagram of a process of operation S704 shown in FIG. 7 in an example. As shown in FIG. 8, in the example of the present disclosure, the above operation S704 may further comprise the following operation S802. FIG. 8 shows related operations in the process of forming the second semiconductor structure in operations S802 and S804, the execution sequence of which may be designed according to actual needs, which is not limited in the present disclosure.

In operation S802, a peripheral circuit structure on the first surface of the substrate is formed.

For example, with continued reference to FIG. 15, a peripheral circuit structure 3042 may be formed on the first surface 30412 of the substrate 3041.

In the process of forming the second semiconductor structure in operation S704, a structure connecting the peripheral circuit structure with other structures may also be formed. For example, operation S804 of forming a first connection structure connected with the peripheral circuit structure on a second surface of the substrate may be included.

For example, with continued reference to FIG. 18, a routing layer comprising the first connection structure 3046 may be formed on the second surface 30414 of the (thinned) substrate 3041 of the second semiconductor structure 304 in FIG. 17. Operation S804 may be performed, for example, between operations S708 to S710.

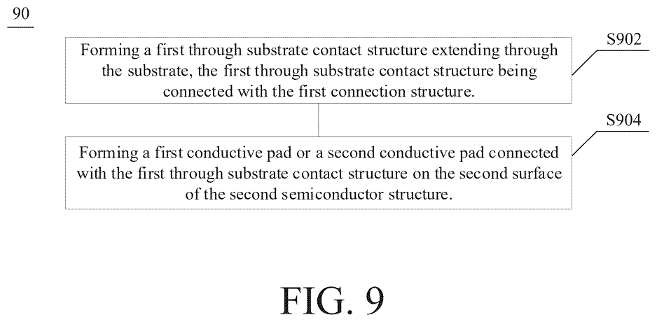

FIG. 9 illustrates a schematic diagram of a process of operations S708 and S710 shown in FIG. 7 in an example. As shown in FIG. 9, in an example of the present disclosure, the foregoing operation S708 may further comprise the following operation S902, and operation S710 may further comprise the following operation S904. FIG. 9 shows a related formation process of connecting the first conductive pad or the second conductive pad to the peripheral circuit structure through the first through substrate contact structure in operations S902 and S904, the execution sequence of which may be designed according to actual needs, which is not limited in the present disclosure.

In operation S902, a first through substrate contact structure extending through the substrate is formed, and the first through substrate contact structure is connected with the first connection structure.

With continued reference to FIG. 18, after forming the first through substrate contact structure 3062 extending through the substrate 3041 along the Y direction, in the process of forming the routing layer comprising the first connection structure 3046 by implementing operation S804, the first connection structure 3046 is connected with the first through substrate contact structure 3062.

In operation S904, a first conductive pad or a second conductive pad connected with the first through substrate contact structure is formed at the second surface of the second semiconductor structure.

With continued reference to FIG. 18, a routing layer comprising the first connection structure 3046 may be formed at the second surface 30414 of the substrate 3041 of the second semiconductor structure 304, and then the first conductive pad 30442 or the second conductive pad 30444 connected with the first through substrate contact structure 3062 through the routing layer may be formed on the second surface 30484 of the second semiconductor structure 304 outside the routing layer.

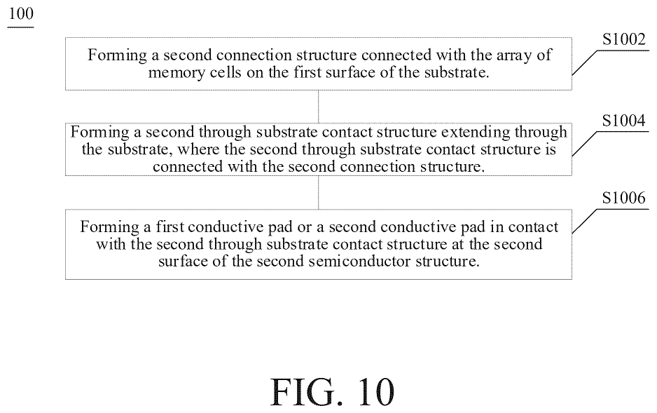

FIG. 10 illustrates a schematic diagram of a process of operations S704, S708 and S710 shown in FIG. 7 in an example. As shown in FIG. 10, in an example of the present disclosure, the foregoing operation S704 may further comprise the following operation S1002, the operation S708 may further comprise the following operation S1004, and the operation S710 may further comprise the following operation S1006. FIG. 1 shows a related formation process of connecting the first conductive pad or the second conductive pad to the array of memory cells through the second through substrate contact structure in operations S1002 to S1006, the execution sequence of which may be designed according to actual needs, which is not limited in the present disclosure.

In operation S1002, a second connection structure connected with the array of memory cells is formed on the first surface of the substrate.

With continued reference to FIG. 15, after forming the peripheral circuit structure 3042 on the first surface 30412 of the substrate 3041 of the second semiconductor structure 304, a second connection structure 1502 may be formed, and the second connection structure 1502 may be connected with the array of memory cells 3022 through the bonding structure in the bonding layer. Operation S1004 may be performed, for example, in operation S704 and before operation S706.

In operation S1004, a second through substrate contact structure extending through the substrate is formed, and the second through substrate contact structure is connected with the second connection structure.

With continued reference to FIG. 18, a second through substrate contact structure 3064 extending through the substrate 3041 along the Y direction is formed to connect the second through substrate contact structure 3064 with the second connection structure 1502.

In operation S1006, a first conductive pad or a second conductive pad in contact with the second through substrate contact structure at the second surface of the second semiconductor structure is formed.

With continued reference to FIG. 18, a routing layer may be formed at the second surface 30414 of the substrate 3041 of the second semiconductor structure 304, and then the first conductive pad 30442 or the second conductive pad 30444 connected with the second through substrate contact structure 306 through the routing layer may be formed on the second surface 30484 of the second semiconductor structure 304 outside the routing layer.

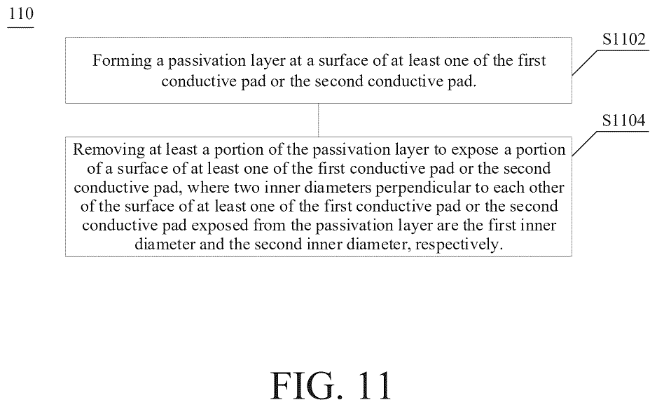

FIG. 11 is a flow diagram illustrating another method of forming a semiconductor structure according to an example. The method illustrated in FIG. 11 may comprise, for example, the operation of forming a passivation layer of the first conductive pad or the second conductive pad surface in FIG. 4A to FIG. 5.

Referring to FIG. 11, the method 110 provided in an example of the present disclosure may comprise the following operations S1102 to S1104, for example, may be performed in a process of performing operation S710, and may be performed after operation S710, for another example.

In operation S1102, a passivation layer is formed at a surface of at least one of the first conductive pad or the second conductive pad.

In some examples, a passivation layer may be deposited onto an exposed surface of at least one of the first conductive pad or the second conductive pad by a thin film deposition technique.

In operation S1104, at least a portion of the passivation layer is removed to expose a portion of a surface of at least one of the first conductive pad or the second conductive pad, where two inner diameters perpendicular to each other of the surface of at least one of the first conductive pad or the second conductive pad exposed from the passivation layer are the first inner diameter and the second inner diameter, respectively.

In some examples, a central portion of the surface of at least one of the first conductive pad or the second conductive pad covered with the passivation layer may be removed by an etching technique such as Chemical Mechanical Polishing (CMP). For example, the passivation layer at the outer ring in FIG. 4A to FIG. 5 may be retained to expose the central portion having the first inner diameter and the second inner diameter, so as to realize electrical connection between at least one of the array of memory cells or the peripheral circuit structure and the outside.

Examples of the present disclosure are shown and described in detail above. It should be understood that the present disclosure is not limited to the detailed structures, arrangements, or implementation methods described herein; rather, the present disclosure is intended to cover various modifications and equivalent arrangements included within the spirit and scope of the appended claims.

What is claimed is:

1. A semiconductor structure, comprising:
a first semiconductor structure comprising an array of memory cells; and
a first conductive pad and a second conductive pad disposed at a surface of the semiconductor structure,
wherein the array of memory cells is connected with the first conductive pad and the second conductive pad respectively at least through different contact structures, wherein the contact structures at least partially extend through the semiconductor structure along a first direction, wherein the first direction is perpendicular to the surface of the semiconductor structure, wherein the first conductive pad is at least one of a polygon, a circle or an ellipse, wherein the polygon has more than 4 sides, wherein a surface of the second conductive pad is connected with at least one conductive line, and wherein the second conductive pad is a quadrangle.

2. The semiconductor structure according to claim 1, wherein the first conductive pad and the second conductive pad each have a first inner diameter and a second inner diameter perpendicular to each other, wherein a length of the first inner diameter of the first conductive pad is equal to a length of the first inner diameter of the second conductive pad, and wherein a length of the second inner diameter of the first conductive pad is equal to a length of the second inner diameter of the second conductive pad.

3. The semiconductor structure according to claim 2, wherein an area of the first conductive pad is smaller than an area of the second conductive pad.

4. The semiconductor structure according to claim 1, further comprising a second semiconductor structure, wherein a first surface of the second semiconductor structure is connected with the first semiconductor structure; and
the first conductive pad and the second conductive pad are both disposed at a second surface of the second semiconductor structure.

5. The semiconductor structure according to claim 4, wherein the second semiconductor structure comprises a peripheral circuit structure connected with the array of memory cells, wherein the contact structure comprises a first through substrate contact structure extending through a substrate of the peripheral circuit structure, and wherein the peripheral circuit structure is connected with a corresponding one of the first conductive pad or the second conductive pad at least through the first through substrate contact structure.

6. The semiconductor structure according to claim 5, wherein the contact structure further comprises a second through substrate contact structure extending through the substrate of the peripheral circuit structure, and wherein the array of memory cells is connected with a corresponding one of the first conductive pad or the second conductive pad at least through the second through substrate contact structure.

7. The semiconductor structure according to claim 5, further comprising a connection structure, wherein the contact structure is connected with a corresponding one of the first conductive pad or the second conductive pad through the connection structure.

8. The semiconductor structure according to claim 2, further comprising a passivation layer disposed around at least one of the first conductive pad or the second conductive pad, and two inner diameters perpendicular to each other of a surface of at least one of the first conductive pad or the second conductive pad exposed from the passivation layer are the first inner diameter and the second inner diameter, respectively.

9. The semiconductor structure according to claim 1, wherein the first conductive pad is a regular polygon.

10. The semiconductor structure according to claim 1, wherein the first conductive pad is an octagon or a hexadecagon.

11. The semiconductor structure according to claim 2, wherein the second conductive pad is a rectangle, and wherein a length and a width of the second conductive pad are the first inner diameter and the second inner diameter, respectively.

12. A method of forming a semiconductor structure, comprising:
forming a first semiconductor structure comprising an array of memory cells;
forming a second semiconductor structure on a substrate, the second semiconductor structure comprising a peripheral circuit structure;
bonding a first surface of the second semiconductor structure with the first semiconductor structure to connect the peripheral circuit structure with the array of memory cells;
forming a contact structure extending through the substrate along a first direction perpendicular to the first surface;
forming a first conductive pad and a second conductive pad connected with different contact structures respectively at a second surface of the second semiconductor structure to connect the array of memory cells with the first conductive pad and the second conductive pad, the second surface being opposite to the first surface, wherein the first conductive pad is at least one of a polygon, a circle or an ellipse, wherein the polygon has more than 4 sides, and wherein the second conductive pad is a quadrangle; and
forming at least one conductive line connected with a surface of the second conductive pad.

13. The method of claim 12, wherein the first conductive pad and the second conductive pad each have a first inner diameter and a second inner diameter perpendicular to each other, wherein a length of the first inner diameter of the first conductive pad is equal to a length of the first inner diameter of the second conductive pad, and wherein a length of the second inner diameter of the first conductive pad is equal to a length of the second inner diameter of the second conductive pad.

14. The method according to claim 13, wherein an area of the first conductive pad is smaller than an area of the second conductive pad.

15. The method according to claim 12, wherein forming the second semiconductor structure on the substrate comprises:
forming the peripheral circuit structure on a first surface of the substrate; and
forming a first connection structure connected with the peripheral circuit structure on a second surface of the substrate.

16. The method according to claim 15, wherein:
the contact structure comprises a first through substrate contact structure;
forming the contact structure extending through the substrate along the first direction comprises forming a first through substrate contact structure extending through the substrate, wherein the first through substrate contact structure is connected with the first connection structure; and
forming the first conductive pad and the second conductive pad connected with different contact structures respectively at the second surface of the second semiconductor structure comprises forming the first conductive pad or the second conductive pad connected with the first through substrate contact structure at the second surface of the second semiconductor structure.

17. The method according to claim 15, wherein:
the contact structure further comprises a second through substrate contact structure;
forming the second semiconductor structure on the substrate further comprises forming a second connection structure connected with the array of memory cells on the first surface of the substrate;
the method further comprises forming the second through substrate contact structure extending through the substrate, wherein the second through substrate contact structure is connected with the second connection structure; and
forming the first conductive pad and the second conductive pad connected with different contact structures respectively at the second surface of the second semiconductor structure comprises forming the first conductive pad or the second conductive pad in contact with the second through substrate contact structure at the second surface of the second semiconductor structure.

18. The method according to claim 13, further comprising:
forming a passivation layer at a surface of at least one of the first conductive pad or the second conductive pad; and
removing at least a portion of the passivation layer to expose a portion of the surface of at least one of the first conductive pad or the second conductive pad, wherein two inner diameters perpendicular to each other of the surface of at least one of the first conductive pad or the second conductive pad exposed from the passivation layer are the first inner diameter and the second inner diameter, respectively.

19. The method according to claim 12, wherein the first conductive pad is a regular polygon.

20. A semiconductor device, comprising:
a semiconductor structure, comprising:
a first semiconductor structure comprising an array of memory cells; and
a first conductive pad and a second conductive pad disposed at a surface of the semiconductor structure, wherein the array of memory cells is connected with the first conductive pad and the second conductive pad respectively at least through different contact structures, wherein the contact structures at least partially extend through the semiconductor structure along a first direction, wherein the first direction is perpendicular to the surface of the semiconductor structure, wherein the first conductive pad is at least one of a polygon, a circle or an ellipse, wherein the polygon has more than 4 sides, wherein a surface of the second conductive pad is connected with at least one conductive line, and wherein the second conductive pad is a quadrangle.
